(19) United States
(12) Patent Application Publication
(10) Pub. No.: US 2006/0194417 A1
(43) Pub. Date: Aug. 31, 2006

(54) Polycrystalline sillicon substrate

(75) Inventors: Shunichi Ishihara, Kyoto-fu (JP); Katsumi Nakagawa, Kanagawa-ken (JP); Hiroshi Sato, Nara-ken (JP); Takehito Yoshino, Tokyo (JP); Shoji Nishida, Kanagawa-ken (JP); Noritaka Ukiyo, Kanagawa-ken (JP); Masaaki Iwane, Kanagawa-ken (JP); Yukiko Iwasaki, Kanagawa-ken (JP); Masaki Mizutani, Shizuoka-ken (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/530,189

(22) PCT Filed: Oct. 10, 2003
(86) PCT No.: PCT/JP03/13074

§ 371 Date: Feb. 3, 2006

(30) Foreign Application Priority Data
Oct. 16, 2002 (JP) NO.2002-302286

(51) Int. Cl. H01L 31/0376; H01L 21/20

(52) U.S. Cl. 438/479; 257/53

(57) ABSTRACT

A polycrystalline silicon substrate for a solar cell formed by growing a high purity polycrystalline silicon layer on a surface of a base obtained by slicing a polycrystalline silicon ingot obtained by melting metallurgical grade silicon and performing one-direction solidification, wherein one-direction solidification is performed on a melt prepared by adding B to molten metallurgical grade silicon at an amount of 2×10¹⁸ cm⁻³ to 5×10¹⁹ cm⁻³ based on the concentration in the melt to produce the polycrystalline silicon ingot. With this structure, it is possible to easily obtain a polycrystalline silicon substrate having resistivity and the type of conductivity suitable for manufacture of a solar cell.

### TECHNICAL FIELD

The present invention relates to a polycrystalline silicon substrate, which is inexpensive and hardly suffers a restriction of silicon resources in a production thereof.

### BACKGROUND ART

A solar cell has been widely used as an awareness regarding an environmental issue is growing up. A monocrystalline or polycrystalline silicon substrate is mainly used for manufacturing a solar cell for the general purpose. Basically, monocrystalline silicon for a solar cell is pulled up by a Czochralski method similarly to the case that silicon for a semiconductor is produced. On the other hand, since polycrystalline silicon can be produced by melting and solidifying silicon in a crucible, a throughput in the production is higher than that of monocrystalline silicon. However, since off-grade silicon wafer in IC industry or the like, or residual silicon in the Czochralski crucible-drawing process is used as a raw material for polycrystalline silicon in many cases, a supply amount is limited and it is difficult to lower a price much.

Therefore, an attempt has been made that polycrystalline silicon, which is produced using inexpensive unpurified silicon (metallurgical grade silicon) being obtained by merely reducing a silica stone, is purified without performing a silicon purifying process for a semiconductor such as a Siemens method. For example, K. Hanazawa, M. Abe, H. Baba, N. Nakamura, N. Yuge, Y. Sakaguchi, Y. Kato, S. Hiwasa, and M. Obashi propose a technique in which phosphorous and boron which are contained at a large amount in metallurgical grade silicon are removed by utilizing an electron beam (EB) gun or a plasma torch to obtain a silicon material for a solar cell (12^{th} PVSEC Jun. 11-15, 2001 proceeding pp. 265-268). However, even with this method, since it is especially difficult to remove boron and a two-step process is required, reduction in cost to an expected level cannot be achieved yet.

Furthermore, an attempt has been made that polycrystalline silicon is directly grown on a base made of a material other than silicon. Since it is necessary to perform the growth at a high temperature of usually 1,000 to 1,500° C., metal and glass are hard to be used as the base in view of heat resistance and matching of a coefficient of thermal expansion with that of silicon. Therefore, glassy carbon or ceramics was trially used for the base. However, since a polycrystalline silicon film grown on such a base tends to have a small crystal grain and evenness of the surface thereof tends to be deteriorated, such a material is not practically used yet. In addition, glassy carbon or ceramics is never be regarded as an inexpensive material usable for a solar cell.

In view of the above, a method has been proposed, which includes: preparing a base by using inexpensive metallurgical grade silicon; growing a high purity silicon layer having a predetermined thickness on the base to produce a substrate; and manufacturing a solar cell by using the substrate. For example, Haruo ITO, Tadashi SAITOH, Noboru NAKAMURA, Sunao MATSUBARA, Terunori WARABISAKO, and Takashi TOKUYAMA experimentally manufactured a solar cell by growing a polycrystalline silicon on a metallurgical grade silicon base by a CVD method using SiH₂Cl₂ (J. Crys. Growth 45(1978) 446-453). Also, Noguchi, Sano, and Iwata propose a solar cell manufactured by growing high purity polycrystalline silicon of semiconductor grade on a solar cell metallurgical grade silicon base in Japanese Patent. Application Laid-Open No. H5-036611, claims 1 to 3.

According to these methods, since a base is made of silicon although the base has low purity, a problem of heat resistance or incompatibility in coefficient of thermal expansion is not caused. Furthermore, since a grown polycrystalline silicon film takes over crystallinity of the base, a polycrystal having better quality can be grown compared to the case that glassy carbon or ceramics is used as the base. However, in a method of growing silicon in a vapor phase such as CVD, there exist problems in that the number of bases which are supplied for one batch is limited and in that a growing film may come off the inner wall of the apparatus. Furthermore, in the case of performing growth on a base made of silicon having low purity such as metallurgical grade silicon, an impurity such as a metal, B, or P contained in the base tends to be incorporated again into a high purity silicon layer after the impurity is once liberated into a vapor phase. As a result, even if purity of raw material silicon gas to be used is increased, there exists a strong tendency that a grown silicon layer is contaminated with metal or becomes to have inappropriately low resistivity for manufacturing a solar cell.

T. H. Wang, T. F. Ciszek, C. R. Schwertfeger, H. M. Mountinho, and R. Matson propose a method utilizing a liquid phase growth method for growing a high purity silicon layer on a metallurgical grade silicon (Solar Cell Materials and Solar Cells 41/42(1996) 19-30). Also, Nishida proposes in Japanese Patent Application Laid-Open No. H10-098205 that a high purity silicon layer be grown by a liquid phase method on a metallurgical grade silicon base so as to be used for a solar cell. Furthermore, various novel methods are disclosed regarding a base forming method. The novel methods are useful means for reducing a cost of a solar cell.

According to a liquid phase growth method, since a thick silicon layer can be easily grown and a proportion of waste silicon among a silicon material to be used is small, this method is highly suitable for manufacturing a solar cell. Furthermore, since an influence of an impurity in a base on a high purity silicon layer is smaller than that in vapor phase growth by controlling a degree of supersaturation of a melt, a high quality polycrystalline silicon layer can be relatively easily obtained. Therefore, the method is highly suitable for forming a substrate using a metallurgical grade silicon base. Nevertheless, an influence of an impurity remains. Especially, there remains a problem in that properties of a manufactured solar cell largely vary depending on a batch of a silicon material used for producing a base. Furthermore, regardless of the type of method of growing a high purity silicon layer, there exists a tendency that a manufacturing line of a solar cell is contaminated with an impurity contained in a base so that properties of a manufactured solar cell are affected. Therefore, it has been conceivable that low purity silicon such as metallurgical grade silicon is hard to be used as it is for the production even if such silicon is inexpensive. Also, growth of a thick silicon layer requires much time and a large amount of a silicon material, thereby causing an increase in cost. In order to sufficiently utilize incident light even in the case of a relatively thin silicon layer, minute uneven structure referred to as a texture is desirably formed on the surface of a crystal. However, if the texture is formed by etching as generally done, a part of the silicon layer which has been grown is lost. Furthermore, such formation is not preferred in view of light absorption.

As described above, there still remain many problems regarding production of a substrate for a solar cell using low purity silicon, e.g., metallurgical grade silicon, as a base and manufacture of a solar cell using such a substrate.

### DISCLOSURE OF THE INVENTION

It is an object of the present invention to provide a substrate for a solar cell using low purity silicon as a main raw material and being capable of remarkably reducing cost compared to a conventional polycrystalline silicon substrate, and being capable of obtaining conversion efficiency as much as that of a conventional polycrystalline silicon substrate when a solar cell is manufactured.

The present invention has been made in view of the above-mentioned problems and relates to a novel silicon substrate for a solar cell which is obtained by growing a high purity polycrystalline silicon layer on a base formed by slicing an ingot produced by using low purity silicon represented by metallurgical grade silicon.

The present invention provides a polycrystalline silicon substrate for a solar cell formed by growing a high purity polycrystalline silicon layer on a surface of a base obtained by slicing a polycrystalline silicon ingot obtained by melting metallurgical grade silicon and performing one-direction solidification, wherein one-direction solidification is performed on a melt prepared by adding B to molten metallurgical grade silicon at an amount of 2×10¹⁸ cm⁻³ to 5×10¹⁹ cm⁻³ based on a concentration in the melt to the produce the polycrystalline silicon ingot.

Further, the present invention provides a polycrystalline silicon substrate for a solar cell formed by growing a high purity polycrystalline silicon layer on a surface of a base obtained by slicing a polycrystalline silicon ingot obtained by melting metallurgical grade silicon and performing one-direction solidification, wherein one-direction solidification is performed on a melt prepared by adding Al to molten metallurgical grade silicon at an amount of 1×10¹⁹ cm⁻³ to 1×10²¹ cm⁻³ based on a concentration in the melt to produce the polycrystalline silicon ingot.

### BRIEF DESCRIPTION OF THE DRAWINGS

FIG. 1 is a view illustrating a cross section of a polycrystalline silicon substrate according to the present invention.

FIG. 2 is a view illustrating a cross section of another polycrystalline silicon substrate according to the present invention.

FIG. 3 is a view illustrating a cross section of a polycrystalline silicon solar cell manufactured by a method according to the present invention.

FIG. 4 is a view illustrating a configuration of a polycrystalline silicon ingot producing apparatus preferably used for practice of the present invention.

FIG. 5 is a view illustrating a configuration of a liquid phase growth apparatus preferably used for practice of the present invention.

FIG. 6 is a view illustrating a configuration of another liquid phase growth apparatus preferably used for practice of the present invention.

### BEST MODE FOR CARRYING OUT THE INVENTION

(Raw Material Silicon)

A silicon material, which is lowest-priced and a supplied amount of which is large, is metallurgical grade silicon obtained by directly reducing silica stone. The metallurgical grade silicon is not produced in Japan and is imported from Norway, Brazil, China and the like. Although its purity is officially announced as 97% or more in general, the type and a concentration of an impurity actually contained in the metallurgical grade silicon vary depending on raw material silica stone. A typical example is shown in Table 1.

TABLE 1

| Impurity | Concentration |
|---|---|
| Fe | 1000 ppmw |
| Al | 800 ppmw |
| Cu | 15 ppmw |
| Cr | 10 ppmw |
| B | 10 ppmw |
| P | 50 ppmw |

Examples of the major impurity include a heavy metal such as Fe, Cr, or Cu. Since such an impurity forms a deep level in silicon and acts as a recombination center, properties of a solar cell are remarkably deteriorated. Furthermore, since a heavy metal is easy to diffuse, if a heavy metal is contained at a high concentration in a material for a base, contamination tends to be widely spread in a growing process of a high purity silicon layer and a manufacturing process of a solar cell. In addition, metal impurities aggregate to form a fine particle, which may cause a solar cell to shunt.

Furthermore, an impurity such as B, Al, or P which can serve as a dopant is contained in the metallurgical grade silicon at a high concentration. Resistivity and the type of conductivity of an ingot are determined in accordance with the concentration of such a dopant and a relative amount of p-type dopant to n-type dopant. The ingot may be p-type or n-type.

Even in the case of a semiconductor grade or solar cell grade silicon material containing an impurity other than Al, B, or P at a low concentration, when resistivity thereof is less than a predetermined range (approximately 0.1 Ω·cm or less, as described later), a solar cell manufactured by using the material as it is has low efficiency and is not practicable. Since such a raw material contains a dopant impurity such as Al, B, or P at higher concentration than a practically acceptable level, the material can not be used for manufacturing a device. Therefore, since such a material is available at a significantly lower price compared to usual high purity silicon, the material is effectively used as “low purity silicon” as a raw material in the present invention.

(Description of Process of Producing Substrate for Solar Cell)

(Formation and Slice of Ingot)

Raw material silicon filled in a crucible is molten and solidified to obtain an ingot of polycrystalline silicon. The ingot is sliced to a predetermined thickness by a wire saw to form a polycrystalline silicon base. An ingot solidifying apparatus preferably used for practice of the present invention is shown in FIG. 4. It is desirable that solidification of the raw material silicon molten in the crucible 201 gradually progress from the bottom face to the surface of the crucible (along a growing direction 207) while an interface between a solidified portion 205 and a molten portion 206 being kept level. For that purpose, it may be such that a support 204 for the crucible 201 is slowly moved down in a temperature gradient from an upper portion to a lower portion of the crucible 201 formed by a cylindrical heater 202 having three sections and being mounted at the side of the apparatus, thereby performing cooling. A heater 203 is used for forming a temperature gradient from the upper portion to the lower portion. A crystal grain is grown from the bottom face to the surface of the crucible 201. Such a solidifying method is referred to as a one-direction solidification. A heavy metal impurity is discharged from the solidified portion 205 to the melt 206 by a segregation effect. As a result, an impurity concentration in the solidified polycrystal is reduced and an impurity is concentrated in the finally remaining melt. If the one-direction solidification is appropriately performed, a concentration of a heavy metal impurity in a polycrystal can be reduced to 1/100 or less compared to that of raw material silicon. However, it is still impossible to use such a polycrystal for manufacturing a solar cell because properties are deteriorated owing to an increase of recombination of a carrier produced by incident light. Furthermore, since a segregation effect of B or P is extremely poor, the concentration thereof can not be reduced by the one-direction solidification. The method by Haruo ITO et al. described above is for removing B and P, which can not be removed by the one-direction solidification, as simply as possible. However, since such a method requires two additional steps compared to the one-direction solidification, the method significantly increases cost.

In the present invention, although a heavy metal is removed by a one-direction solidification as much as possible, an additional purification is not performed. Therefore, if the thus-formed polycrystalline silicon is used for a solar cell as it is, satisfactory properties can not be expected. Furthermore, metallurgical grade silicon generally contains a large amount of P as well as B and Al. Although the concentration of P depends on a production area and a grade, the concentration is generally 30 ppm by weight or more. In addition, as described above, since the segregation effect of P involved in solidification is poor, P is contained in a solidified ingot at a high concentration. In order to form a p-type ingot having predetermined resistivity (300 mΩ or less) by using such metallurgical grade silicon, B or Al is preferably added at an amount which appropriately performs counter dope against an effect of P depending on a production area and a grade of raw material metallurgical grade silicon. However, an adding amount has an upper limitation and must be within a range so that crystallinity of Si is not deteriorated and a crystal grain size is not extremely decreased in particular. With regard to B, such an adding amount is in the range of 2×10¹⁸ cm⁻³ to 5×10¹⁹ cm⁻³ and preferably of 2×10¹⁸ cm⁻³ to 4×10¹⁹ cm⁻³ based on the concentration in silicon melt. Furthermore, since the segregation effect of B involved in solidification is poor as described above, the concentration of B in the silicon melt approximately corresponds to the concentration in the solidified ingot. With regard to Al, the adding amount is in the range of 1×10¹⁹ cm⁻³ to 1×10²¹ cm⁻³ and preferably of 1×10¹⁹ cm⁻³ to 5×10²⁰ cm⁻³ based on the concentration in silicon melt. The adding amount of Al is larger than that of B because a segregation effect of Al is larger than that of B and therefore Al is easily removed by the one-direction solidification, the actual content in the ingot is smaller than that in the melt. As described later, a base formed from such an ingot produces a junction with a polycrystalline silicon layer grown thereon and contributes to improvement of solar cell properties, especially a release voltage. In addition, even if this method is performed, an increase in production cost is small unlike purification.

The formed ingot is sliced into a flat plate having a thickness of 200 to 350 μm by use of an ID blade cutter or a wire saw. A wire saw is preferred for use for a solar cell because the wire saw has high productivity. Since an ingot based on a method according to the present invention is formed by a one-direction solidification method, a crystal grain extends especially long in a growing direction. In the case of forming a substrate from a polycrystalline silicon ingot for a solar cell, in many cases, the ingot is sliced across perpendicularly a crystal growing direction 207. However, in the case of using the ingot as a base as in the present invention, if the ingot is sliced parallel to the growing direction 207, an area per one crystal grain is increased and an undesirable influence of a grain boundary is decreased. Therefore, satisfactory solar cell properties are easily obtained. Since there remains a mark of a wire saw and dirt is attached on the surface of the base just after being sliced, an etching is performed. In many cases, the surface of a substrate for a solar cell is made uneven by an alkali etchant to form a texture structure. However, in the case of a base, it is no meaning to form a texture structure because a surface shape of a silicon layer grown on the base is different from the original surface of the base in many cases and because unusual growth may be caused. Therefore, it is rather preferred that the surface of the base be washed with a solvent and then be subjected to planar etching using a mixed liquid of nitric acid, acetic acid, and hydrofluoric acid=300:68:32 for several minutes to be made flat.

(Liquid Phase Growth)

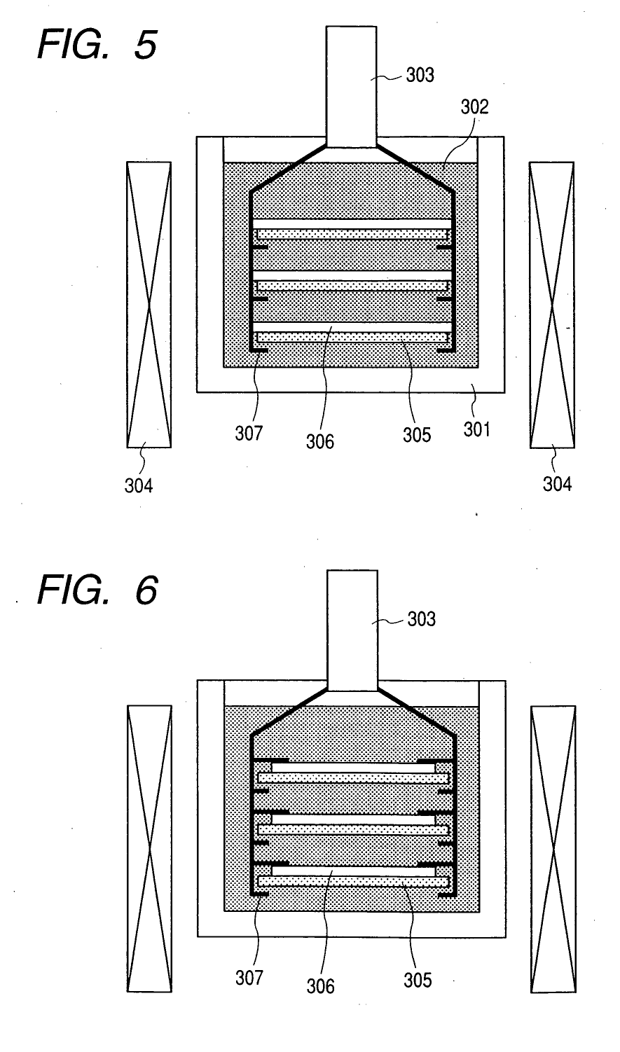

In liquid phase growth of silicon, a metal having a low melting point such as tin, indium, gallium, aluminum, or copper is molten and silicon is dissolved therein to prepare a melt. Of those, indium has an appropriately low melting point and therefore is easy to handle, and furthermore indium is hard to be a solid solution in silicon. Therefore, indium is preferable for growing high quality silicon. Also, since copper has high solubility in silicon, copper is preferable for rapidly growing silicon. FIGS. 5 and 6 are respectively a schematic cross-sectional view of a liquid phase growth apparatus preferred for practice of the present invention. In FIGS. 5 and 6, reference numeral 303 denotes a shaft; 306, a support plate; and 307, a drop preventing claw. Initially, a crucible 301 is heated by a cylindrical heater 304 surrounding the crucible 301 and silicon is saturatedly molten at a temperature of approximately 600° C. to approximately 1,200° C. depending on the kind of an objective melt to form a melt 302. As a silicon material to be molten, although metallurgical grade silicon containing a large amount of an impurity is not appropriate, semiconductor grade silicon (having a purity of approximately 10 N to 11 N) is not required and solar cell grade silicon (having a purity of approximately 6 N to 7 N) is sufficient. Next, a base 305 of polycrystalline silicon is dipped in the melt 302. In each of FIGS. 5 and 6, the case that three bases are used is exemplified. However, growth can be performed on several tens or several hundreds of bases depending on dimensions of the crucible. Usually, prior to performing liquid phase growth, a temperature of the melt 302 is once increased to a temperature higher than a saturation temperature of silicon so as to produce an unsaturated condition, and then the base 305 is dipped in the melt so that a part of the base is dissolved in the melt to adjust the surface of the base to the melt. However, in the case of using metallurgical grade silicon as a base, the adjustment is not preferred because an impurity in the base is dissolved in the melt. If the surface of the base is appropriately subjected to an etching treatment and if a flow of a reducing gas such as hydrogen is formed at the inside of a container that accommodates the base and the crucible, the surface of the base can be adjusted to the melt and an impurity is not dissolved in the melt even if a temperature of the melt is decreased to a temperature approximately several to ten and several ° C. lower than the saturation temperature of silicon and then the base is dipped in the melt.

The base 305 is dipped in the melt 302, and then the melt is cooled. When the melt is cooled, silicon, which becomes incapable of being dissolved in the melt, deposits on the base 305. Since the base is made of polycrystalline silicon, a deposited silicon layer follows the base so as to be polycrystalline. In many cases, the cooling is gradually performed at a constant cooling rate. Such a method is referred to as a slow cooling method. In addition to the slow cooling method, an example of a liquid phase growth method includes a method referred to as a temperature difference method. The temperature difference method includes: dipping a solid solute such as silicon and a base in a melt; keeping the solute at a relatively high temperature and the base at a relatively low temperature; and eluting and diffusing the solute from the surface of the solid solute to grow the solute on the base. Since the temperature difference method can keep the temperatures of the respective parts constant throughout the process, the method is preferably used for growth of a compound semiconductor which requires high evenness of a grown film in a thickness direction. The method is also preferably applied to growth of silicon. The type of conductivity and resistivity of a polycrystalline silicon layer is affected by the melt. Indium, gallium, aluminum, and the like are p-type dopants themselves. Therefore, when such a metal is used for a melt, the dopant is dissolved in silicon in a solid phase to be a p-type silicon layer. Of those, since indium is hardly dissolved in silicon in a solid phase, conductivity is easily controlled. Also, although tin is somewhat dissolved in silicon in a solid phase, since tin is an element of Group IV and therefore is electrically inactive, conductivity is easily controlled. In the case of using a melt of such a metal, it is possible to control p-type or n-type at will by dissolving a dopant such as B, aluminum, gallium, P, or antimony together with silicon in the melt and performing liquid phase growth.

In the case of using a polycrystalline silicon layer as an active layer of a solar cell, resistivity of the polycrystalline silicon layer is preferably approximately 0.1 to 10 Ω·cm. If the resistivity is higher than the range, an n⁺-p junction (or a p⁺-n junction) with an emitter layer is not sufficiently formed. As a result, a release voltage is especially reduced. In contrast, if the resistivity is lower than the range, a depletion layer is not sufficiently spread and furthermore recombination of a carrier is increased. As a result, a short circuit current is especially reduced. On the other hand, it is desirable that the base have the same type of conductivity and lower resistivity. In such a case, a p-p⁺ junction (or an n-n⁺ junction) is formed between the polycrystalline silicon layer and the base to show a back surface field (BSE) effect, absorption of long-wavelength light is enhanced so that a short circuit current is increased, and a release voltage is improved. In general, the base is used as p⁺ (approximately 0.005 to 0.1 Ω·cm) and the polycrystalline silicon layer is used as p (approximately 0.1 to 10 Ω·cm). However, even if the base is used as n⁺ (approximately 0.005 to 0.1 Ω·cm) and the polycrystalline silicon layer is used as n (approximately 0.1 to 10 Ω·cm), the same effect can be obtained.

Furthermore, in the case of using a polycrystalline silicon layer as an active layer of a solar cell, it is desirable that a thickness thereof be at least approximately 100 μm because the thicker polycrystalline silicon layer absorbs more incident light. However, in such a case, since it takes much time to grow the polycrystalline silicon layer and an amount of raw material silicon to be used is increased, an increase in cost is caused. In view of this, as generally employed in a crystalline silicon solar cell, a method may be used, which includes forming a texture structure by etching with an alkali solution or the like to extend an optical path length of incident light thereby enhancing absorption. However, this method is not much preferred because a grown polycrystalline silicon layer is partly lost.

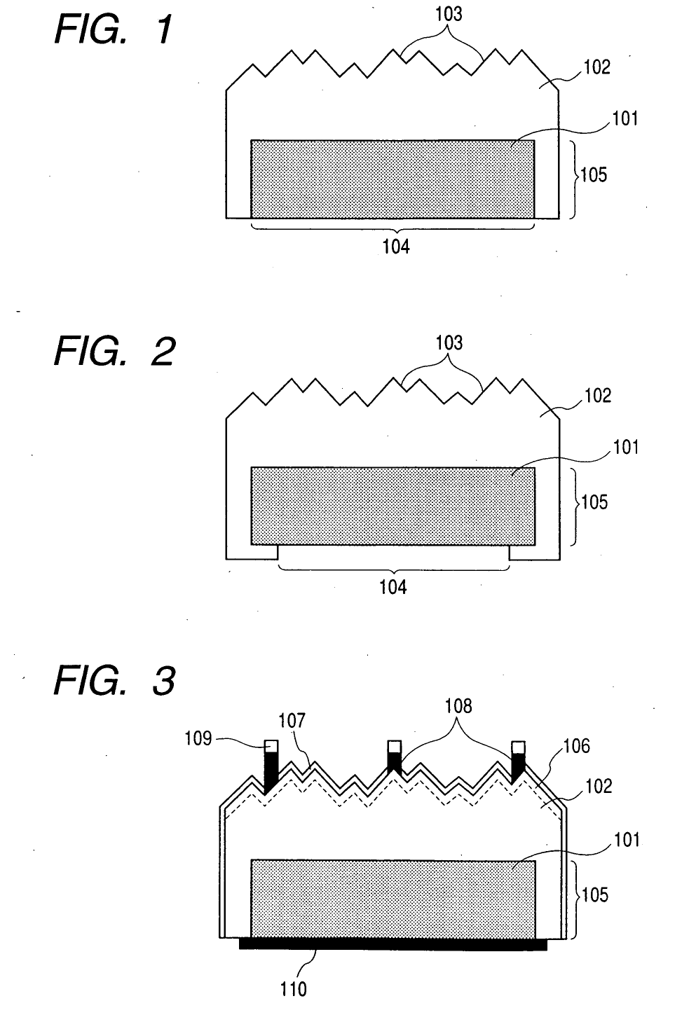

In the case of performing liquid phase growth on a base made of crystalline silicon, a plane having a specific surface orientation, especially (111) surface (a facet surface) tends to preferentially appear on the surface of grown crystalline silicon. This is probably because the liquid phase growth occurs under a condition which is almost equivalent to thermal equilibrium. Conditions in each of which a surface orientation on the surface of the base is other than (111) are shown in FIGS. 1 and 2. Since a facet surface 103 has an inclination against the surface of the base 101, minute unevennesses having a pitch of several μm to several tens of μm are formed on the surface of the polycrystalline silicon layer 102. Furthermore, according to the base of polycrystalline silicon, an orientation of the facet surface 103 is uniform in each crystal grain. On the other hand, the orientation is different from that in the different crystal grain. Therefore, orientations of the base are random as a whole. By virtue of the action of the minute unevennesses formed on the facet surface, the polycrystalline silicon layer 102 having a thickness of approximately only 20 to 50 μm has light absorption equivalent to that of a flat polycrystalline silicon layer having a thickness of 100 μm. Since this method can utilize the entire grown silicon unlike a method employing etching and does not require an etching process, the method is advantageous in view of cost.

According to the present invention, a dopant element is contained in a base at a high concentration. Furthermore, especially in the case of using metallurgical grade silicon as a raw material, a heavy metal impurity which can not be removed is contained in the base. In the case of using such a base, there is a possibility that the dopant element or the heavy metal impurity diffuses from the exposed surface of the base to the inside of a processing apparatus in the process of manufacturing a solar cell, so as to give an undesirable influence on properties of the resultant solar cell. Especially, the influence easily appears in a thermal diffusion process for forming a surface emitter layer (an n⁺ layer in the case where a polycrystalline silicon layer is of p-type) by way of a high temperature. In view of preventing diffusion of an impurity, it is preferred that the entire area of the base be covered with a high purity polycrystalline silicon layer at the time of performing liquid phase growth. On the other hand, if the back surface of the base is covered with a polycrystalline silicon layer having relatively high resistivity, electrical contact on the back surface is hard to be made. Therefore, as shown in FIGS. 1 and 2, it is preferred that the liquid phase growth be performed so that the base surface is exposed in a predetermined area on the back surface of the base 101 and the surface and the end surface 105 of the base be entirely covered with a high purity polycrystalline silicon layer 102. FIG. 1 shows the case where an exposed portion 104 is formed on the entire back surface and FIG. 2 shows the case where an exposed portion 104 is formed on a predetermined portion of the back surface. When the thus obtained substrate is used for a process of manufacturing a solar cell, a cover is placed on the exposed portion 104 or two substrates are overlapped back to back so that diffusion of an impurity can be suppressed. Furthermore, since the exposed portion 104 has low resistivity, electrical contact on the base is easily made.

A mechanism, which forms the exposed portion 104 only on the back surface of a base in liquid phase growth, is incorporated in each apparatus shown in FIGS. 5 and 6. According to the apparatus of FIG. 5, the base 305 is supported between the support plate 306 and the drop preventing claw 306. Although the drop preventing claws 307 are shown only at two positions in the cross-sectional view, at least three drop preventing claws are actually mounted to stably support the base 305. When the base 305 is dipped in the melt 302, the base 305 having a specific gravity smaller than that of the melt 302 is firmly attached to the support plate 306 by buoyancy as shown in FIGS. 5 and 6. Furthermore, the support plate 306 is made somewhat larger than the base 305. As a result, growth occurs on the surface and the end surface of the base while growth does not occur at all on the back surface of the base. In contrast, according to the apparatus of FIG. 6, since the support plate 306 is made somewhat smaller than the base 305, growth occurs at the peripheral on the back surface of the base as well as on the surface and the end surface thereof. However, since growth does not occur at the portion which is firmly attached to the support plate 307, an exposed portion as shown in FIG. 2 is formed.

(Description of Process for Manufacturing Solar Cell)

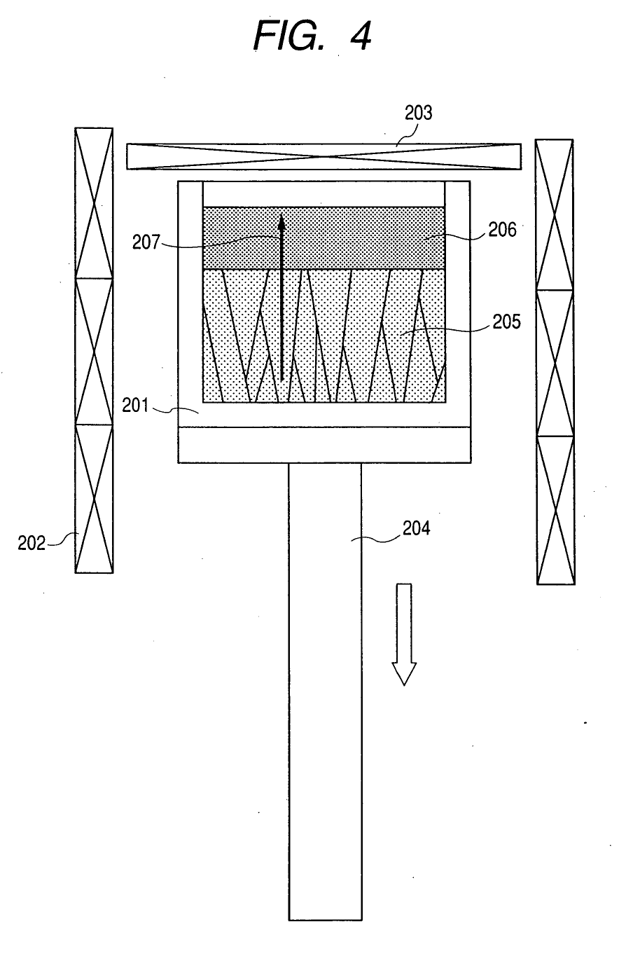

A cross sectional structure of an example of a solar cell manufactured on a substrate according to the present invention is shown in FIG. 3.

(Formation of Emitter Layer)

Examples of a method for forming an emitter layer 106 include: a method which includes growing a polycrystalline silicon layer 102 in a liquid phase and further growing, on the polycrystalline silicon layer, a thin silicon layer which is doped at a high concentration to the type of conductivity opposite to the polycrystalline silicon layer; and a method which includes alternating the type of conductivity at the outermost surface portion of several thousands of angstroms by performing thermal diffusion or ion implantation of a dopant on the surface of the polycrystalline silicon layer. A P₂O₅ layer, which is formed on the surface of the polycrystalline silicon layer by oxidizing the surface of the polycrystalline silicon layer while an application liquid containing P is applied or an inactive gas containing POCl₃ is flown, can be employed as an n-type diffusion source. A B₂O₃ layer, which is formed on the surface of the polycrystalline silicon layer by oxidizing the surface of the polycrystalline silicon layer while an inactive gas containing BBr₃ is flown, can be employed as a p-type diffusion source. The depth of a junction of the emitter layer is possibly approximately 1,000 to 5,000 angstroms and surface sheet resistivity may be approximately 10 to 100 Ω/□. In order to obtain such an emitter layer by means of a thermal diffusion, a treatment at approximately 700 to 900° C. for several to several tens of minutes is required. However, there is a possibility that an impurity such as B, P, or a heavy metal contained in the base diffuses as described before. In a solid phase, there is very little problem because of the following reasons. B or P has a short diffusion length in a solid phase, contributes to improvement of a BSF effect and therefore gives no undesirable influence even if such a little diffusion occurs, and the concentration of a heavy metal is significantly reduced by one-direction solidification. However, in the process for using a CVD furnace for forming an emitter layer or in the process for performing a thermal diffusion of a dopant in a diffusion furnace to form the emitter layer, there is a possibility that an impurity diffuses in a vapor phase. In contrast, in the case of using the base proposed in the present invention in which at least the surface and the end surface are covered with a high purity polycrystalline silicon layer, the possibility of diffusion of an impurity in a vapor phase can be minimized by placing two bases back to back in the CVD furnace or the diffusion furnace.

(Formation of Reflection Preventing Layer and Grid Electrode)

Since silicon has a large reflectance, specifically a refractive index of approximately 3.4, compared to that of air, it is necessary to form an appropriate reflection preventing layer 107 on the surface thereof. As a reflection preventing layer, a transparent film is used, which is composed of silicon nitride, titanium oxide, zinc oxide, zinc sulfide, or the like, which has high transparency, specifically, a refractive index of approximately 1.8 to 2.3, and which has a thickness of approximately 600 to 900 angstroms. A sputtering method, a thermal CVD method, a plasma CVD method, or the like is generally used as a deposition method of the reflection preventing layer 107. In the case of using titanium oxide, the reflection preventing layer can also be formed by applying an application solution to titanium oxide and baking the whole. In some cases, the reflection preventing film has a function for preventing recombination of a carrier on the surface in addition to an optical function. In view of this, silicon nitride is excellent in particular because silicon nitride is especially advantageous to easily obtain a large photoelectric current.

A grid electrode 108 is formed on the surface of the emitter layer 107 to produce a photoelectric current. Since the grid electrode 108 is an obstacle against incident light, it is desirable that a width of the grid be as narrow as possible and the number of the grid be as small as possible. Also, since a current intensively flows in the grid electrode, resistivity thereof is preferably as low as possible. Furthermore, it is necessary for the grid electrode 108 to form satisfactory electrical contact with the emitter layer 106. In view of this, in general, a pattern of a silver paste containing a glass frit is printed and baked to form the grid electrode. Since the above-mentioned reflection preventing film generally has high resistivity, it is necessary for the grid electrode 108 to be directly in contact with the emitter layer 106. However, if the reflection preventing layer is formed on the grid electrode, a solder coat 109 is damaged, which is formed on the printed grid electrode to reduce resistivity of the grid electrode. Therefore, a method is employed in which the grid electrode is generally formed after an area of the reflection preventing layer at which the grid electrode should be formed is etched in advance so that the emitter layer is exposed. Alternatively, there is a method (a fire through method), which includes printing a pattern of the grid electrode 108 on the reflection preventing layer 107 and baking the pattern so that the grid electrode runs through the reflection preventing layer to come into contact with the emitter layer 106. This method is becoming widely used because it is not necessary to perform etching of the reflection preventing layer and adjustment of the electrode pattern and therefore the method offers high productivity.

(Formation of Back Electrode and Isolation of Emitter Layer)

According to a general crystalline silicon solar cell, in the case where a polycrystalline silicon layer is of p-type in particular, a back electrode 110 is often formed by printing an aluminum paste and baking the whole to make electrical contact on the back surface. The aluminum paste is relatively inexpensive. Furthermore, aluminum diffuses in the substrate to form a back surface field (BSF) layer 111 so that efficiency for utilization of a carrier produced in the vicinity of the back surface is improved. As a result, sensitivity of long-wavelength incident light is improved. Therefore, the aluminum paste is widely adopted. In many cases, the aluminum paste shrinks by baking to deflect the substrate and the deflection is especially remarkable if the back electrode is formed on the entire back surface. In this regard, since the base has low resistivity according to the present invention, the back electrode 110 is not necessarily formed on the entire back surface as shown in FIG. 3 and therefore a divided pattern is sufficient. In such a case, it is easy to use the substrate since deflection is small even if the aluminum paste is used.

As described above, the emitter layer 106 is formed on the surface of a polycrystalline silicon layer. If the emitter layer comes into contact with the back electrode 110 or the surface of the base, properties of a solar cell are remarkably deteriorated owing to leakage of photoelectric current. According to the present invention, since at least the surface and the end surface 105 of the base are substantially covered with a polycrystalline silicon layer, there is only a small possibility of such leakage. Furthermore, if the substrates are treated while the substrates are overlapped back to back in a CVD process or a thermal diffusion process for forming an emitter layer, especially the emitter layer is hard to be formed on the back surface so that the possibility of leakage is further decreased. However, in the case where it is especially necessary to suppress leakage between the emitter layer 106 and the back electrode 110 or the base 101, it is preferred that isolation be performed using the following method: a method which includes printing a diffusion source of a dopant in a pattern keeping away from the peripheral portion of the substrate to form an emitter layer, a method which includes etching an emitter layer in the peripheral portion of the substrate to be removed, or a method which includes scribing the surface of the peripheral portion of the substrate. In the case of etching or scribing the emitter layer in the peripheral portion of the substrate, it is desirable that the emitter layer in a predetermined area be substantially removed. On the contrary, if the emitter layer is removed to the extent that the surface of the base is exposed, leakage is caused more easily. Therefore, it is necessary to control the depth to be removed. Furthermore, in the case of using a substantially insulating reflection preventing film such as silicon nitride, if isolation is performed prior to formation of the reflection preventing film, an effect of preventing leakage is further enhanced.

### EXAMPLE 1

An ingot was produced using a mass of 1 to 25 mm of chemical grade metallurgical grade silicon produced in Brazil as a raw material. 1,800 g of the mass was washed with acid and was then charged into an apparatus of FIG. 4. A crucible 201 is made of carbon and SiN as a releasing agent is applied on the inner surface thereof. Dimensions of the inside of the crucible are 80 mm in diameter and 150 mm in depth. Air in the apparatus was exhausted to 10 Pa and then Ar was flown so that the pressure in the apparatus was 1 atmospheric pressure. A cylindrical side heater 202 having three sections and an upper heater 203 were controlled to heat the crucible to 1,600° C., and then silicon in the crucible was entirely molten in 10 hours and gas was discharged. After that, an output of the side heater 202 was controlled to form a temperature gradient of 50° C. from the upper portion to the lower portion. Under such a condition, a stand 204 supporting the crucible was extremely slowly pulled down to solidify silicon from the bottom of the crucible 201. The solidification was completed in 10 hours and then outputs of both the heaters were gradually decreased to perform cooling for 10 hours. A grain boundary extended in a vertical direction of a solidified ingot. Reference numeral 205 denotes a solidified Si portion and 206 denotes a molten Si portion. The temperature was controlled to grow a crystal in a direction indicated by reference numeral 207 while the interface between the solid phase and the liquid phase being kept level. The ingot was sliced by a band saw into a wafer shape and then the surface thereof was etched. As a result of measurement of resistivity, the type was n-type and the resistivity was 10 Ω·cm. In addition, an ingot was solidified again in the same manner as described above except that B₂O₃ was added to a metallurgical grade silicon raw material at an amount shown in Table 2. A small amount of B₂O₃ was diluted with water and the solution was adjusted so that a predetermined amount of B₂O₃ was added. Resistivity, the type of conductivity, and visually measured crystal grain average size are shown in Table 2. Furthermore, each sample was analyzed for impurity by an ICP method. As a result, a concentration of iron or chromium was 1 ppm or less except a portion within 2.5 cm from the surface of the ingot. The type of conductivity of any sample to which B was added was p-type.

TABLE 2

| | | | Average | |
|---|---|---|---|---|
| | | | size of | |
| Adding | | | crystal | Efficiency |
| amount of | | Resistivity | grain | of solar |
| B₂O₃ (mg) | B (cm⁻³) | (Ω cm) | (mm) | cell |
| 0 | | (n-type) 0.01 | 7 | x |
| 20 | 4.52E+17 | 1 | 7 | x |
| 100 | 2.26E+18 | 0.2 | 7 | ∘ |
| 200 | 4.52E+18 | 0.05 | 7 | ∘ |
| 900 | 2.04E+19 | 0.015 | 7 | ∘ |
| 1800 | 4.07E+19 | 0.004 | 7 | ∘ |
| 2200 | 4.98E+19 | 0.004 | 5 | Δ |
| 3000 | 6.79E+19 | 0.004 | 2 | x |

Metallurgical grade silicon on the thus-obtained wafer was used as a base for the subsequent process. The surface of the base was subjected to planar etching using a mixed liquid of nitric acid, acetic acid, and hydrofluoric acid=300:68:32 for 2 minutes to remove a mark of a wire saw remaining on the base, thereby obtaining a glossy surface.

A polycrystalline silicon layer was grown using a liquid phase growth apparatus. Indium was charged into a crucible 301, was heated to 950° C., and was kept at this temperature to be molten. Then, a p-type solar cell grade polycrystalline silicon plate having a thickness of 3 mm was set in place of the base and was dipped in the molten indium to dissolve silicon in indium to be saturated, thereby preparing a melt 302. The polycrystalline silicon plate was once pulled up and the base which was prepared in advance was set in place of the plate. An atmosphere around the crucible was substituted with hydrogen, and then the melt 302 was cooled at a cooling rate of 1° C./minute. When the temperature of the melt was 945° C., the base was dipped in the melt, growth continued for 1 hour, and then the base was pulled up from the melt. After pulling up of the base, it is observed that a little amount of indium was attached, the base was entirely dipped in hydrochloric acid for 1 hour to remove indium. Then, the base 302 was detached from the apparatus to find that a polycrystalline silicon layer 102 with a thickness of approximately 30 μm was grown on the base 101. Hereinafter, a configuration of a substrate or a solar cell will be described with referring to FIG. 1. When the surface of the polycrystalline silicon layer was observed with a metallurgical microscope, minute unevennesses having a pitch of 5 to 10 μm were recognized. Furthermore, when the polycrystalline silicon layer was additionally cut and the cross section thereof was observed, the unevennesses are formed of a terrace which is oriented in a prescribed direction with regard to each crystal grain and therefore it was judged that the unevenness was a facet surface 103 accompanying crystal growth. Also, when resistivity of the polycrystalline silicon layer grown on an n-type base was measured by a four probe method, the resistivity was 0.8 to 1.2 Ω·cm. The reason why the n-type base was used was for precisely measuring resistivity by forming a depletion layer between the base and the p-type polycrystalline silicon layer 102 to electrically separate the polycrystalline silicon layer from the base. Furthermore, although the polycrystalline silicon layer covered not only the surface of the base but also the entire end surface 106 as shown in FIG. 1, growth of the polycrystalline silicon layer was not recognized on the back surface of the base. As described above, a polycrystalline silicon substrate for a solar cell was completed.

After that, a solar cell was experimentally manufactured using the polycrystalline silicon substrate. Initially, an application liquid containing P was applied with a spinner for forming an emitter layer 106. After the application liquid was dried, the substrate was charged in a heat treatment furnace so as to thermally diffuse P in a nitrogen atmosphere at 900° C. Then, a film formed from the application liquid was etched to be removed. Although the emitter layer was formed approximately only on the surface of the substrate, it was recognized that some emitter layers extended to the end surface. Therefore, just to make sure, the end surface was polished to be isolated from the back surface.

Next, the substrate was charged in a load-lock type plasma CVD apparatus in order to form a silicon nitride film as a reflection preventing film 107. The substrate was spread on a susceptor at a temperature of 300° C. An RF voltage was applied to a cathode opposing to the substrate with flowing mixed gas of silane gas, ammonia gas, and nitrogen gas, and discharge was continuously carried out for 5 minutes to deposit a silicon nitride film on the surface of the substrate. The deposited silicon nitride film 107 was deposited in a manner so as to also cover the end surface 106. When a reflection spectrum on the surface was measured with a spectroreflectometer equipped with an integrating sphere, the spectrum had a minimum at a wavelength of 580 nm and the reflectivity was 10% or less in the range of 450 nm to 1,000 nm. In the case of depositing a silicon nitride film on a silicon wafer whose surface was polished under the same condition as above, a minimum was at 650 nm and the range in which a reflectivity was 10% or less was 550 nm to 800 nm. Therefore, a reflection preventing effect due to a minute unevenness of a facet surface was clearly recognized.

Next, an aluminum paste as a back electrode 110 was printed using a screen printer and dried, and then a pattern of a silver paste as a grid electrode 108 was printed on the surface and dried. The resultant was charged in an infrared belt baking furnace. A zone of 450° C. and a zone of 800° C. were provided in the baking furnace. Two substrates were placed on the belt, and the belt was driven at a speed of 100 mm/minute with flowing a large amount of air. As a result, the two substrates were passed through both zones so that the paste was baked. A silver particle ran through the reflection preventing layer 107 to reach the emitter layer 106 to make satisfactory electrical contact with the emitter layer. Meanwhile, with regard to the aluminum paste, aluminum was molten to make satisfactory electrical contact with the back surface of the base.

Finally, in order to form a solder coat layer 109, two substrates were accommodated at a time in a cassette, and then the cassette was dipped in a flux tank and dried by hot air. After that, the cassette was dipped in a solder flow tank for a predetermined period of time and was then pulled up. The cassette was washed with hot water and then dried. Solder was coated only on the grid of the silver paste.

A property of the thus-manufactured solar cell is also shown in Table 2. In Table 2, symbol X means that conversion efficiency is less than 3%, Δ means that conversion efficiency is 5% to 7%, and ∘ means that conversion efficiency is 8% or more.

### EXAMPLE 2

The ingot obtained in Example 1 in which 200 mg of B₂O₃ was added was cut at the position of 5, 10, 15, 20, 25 and 30 mm respectively from the upper end portion thereof to obtain wafers each of which was used as a base. A solar cell was manufactured in accordance with the procedure described in Example 1. A property of the manufactured solar cell is shown in Table 3. In Table 3, the criteria represented by the symbols X, Δ and ∘ are the same as those in Table 2. A base alone was subjected to a quantitative analysis of Fe by an ICP method. The result thereof is also shown in Table 3.

TABLE 3

| | Fe | P | Property of |
|---|---|---|---|
| Position | (Weight ppm) | (Weight ppm) | solar cell |
| 5 mm | 1000 | 70 | x |
| 10 mm | 200 | 64 | x |
| 15 mm | 100 | 55 | Δ |
| 20 mm | 20 | 45 | ∘ |
| 25 mm | 1 | 38 | ∘ |
| 30 mm | 0.1 | 34 | ∘ |

### EXAMPLE 3

An ingot was produced in accordance with the same procedure as in Example 1 except that Al was incorporated into metallurgical grade silicon in place of B₂O₃. An incorporating amount, resistivity, a visually measured crystal grain average size, and a property of a solar cell are as shown in Table 4. The type of conductivity of any sample to which Al was incorporated was p-type.

TABLE 4

| Incorporating | | | Average size | Efficiency |
|---|---|---|---|---|
| amount of Al | | Resistivity | of crystal | of solar |
| (mg) | Al (cm⁻³) | (Ω cm) | grain (mm) | cell |
| 0 | | (n-type) 0.01 | 7 | x |
| 10 | 7.2E+17 | 1.5 | 7 | x |
| 150 | 1.08E+19 | 0.25 | 7 | ∘ |
| 300 | 2.16E+19 | 0.06 | 7 | ∘ |
| 3000 | 2.16E+20 | 0.03 | 7 | ∘ |
| 7000 | 5.04E+20 | 0.008 | 7 | ∘ |
| 15000 | 1.08E+21 | 0.004 | 5 | Δ |
| 20000 | 1.44E+21 | 0.004 | 2 | x |

### EXAMPLE 4

A solar cell was manufactured on the base which was produced in accordance with the procedure of Example 1 and in which B₂O₃ was added at an amount of 4, 40, 200, 1,500 and, 2,200 mg, respectively. A concentration of Fe, Al, P, or B in a polycrystalline film for the solar cell was measured by SIMS. A concentration of any sample was not more than an SIMS detectable level, specifically, 1 ppm or less.

### INDUSTRIAL APPLICABILITY

According to the present invention, in a silicon substrate for a solar cell formed by growing a high purity polycrystalline silicon layer on the surface of a base obtained by slicing a polycrystalline silicon ingot obtained by melting metallurgical grade silicon and performing one-direction solidification, it is characterized in that the polycrystalline silicon ingot is produced by adding B at an amount of 2×10¹⁸ cm⁻³ to 5×10¹⁹ cm⁻³ or Al at an amount of 1×10¹⁹ cm⁻³ to 1×10²¹ cm⁻³ to the metallurgical grade silicon and then melting the whole and performing one-direction solidification of the melt. By using such a polycrystalline silicon substrate for a solar cell, it is possible to obtain a polycrystalline silicon substrate for a solar cell equivalent to a conventional substrate while a high purity silicon raw material at an amount of 1/10 or less of the conventional one is used. Therefore, it is possible to reduce a cost of a solar cell compared to the case of using a conventional polycrystalline silicon substrate. Furthermore, a production amount is hardly restricted. In addition, since the substrate according to the present invention has the same shape as that of a conventional polycrystalline silicon substrate, if a small modification which does not affect a cost is made, a conventional solar cell manufacturing line can be used just as it is. Therefore, it is not necessary to make a new investment for a solar cell manufacturing line.

1. A polycrystalline silicon substrate for a solar cell formed by growing a high purity polycrystalline silicon layer on a surface of a base obtained by slicing a polycrystalline silicon ingot obtained by melting metallurgical grade silicon and performing one-direction solidification,
wherein one-direction solidification is performed on a melt prepared by adding B to molten metallurgical grade silicon at an amount of 2×10¹⁸ cm⁻³ to 5×10¹⁹ cm⁻³ based on a concentration in the melt to produce the polycrystalline silicon ingot.

2. A polycrystalline silicon substrate for a solar cell formed by growing a high purity polycrystalline silicon layer on a surface of a base obtained by slicing a polycrystalline silicon ingot obtained by melting metallurgical grade silicon and performing one-direction solidification,
wherein one-direction solidification is performed on a melt prepared by adding Al to molten metallurgical grade silicon at an amount of 1×10¹⁹ cm⁻³ to 1×10²¹ cm⁻³ based on a concentration in the melt to produce the polycrystalline silicon ingot.
